(19) United States
(12) Patent Application Publication
(10) Pub. No.: US 2018/0033891 A1
(43) Pub. Date: Feb. 1, 2018

(54) OXIDE SEMICONDUCTOR DEVICE

(71) Applicant: UNITED MICROELECTRONICS CORP., Hsin-Chu City (TW)

(72) Inventors: XIAODONG PU, Singapore (SG); Shao-Hui Wu, Singapore (SG); HAI BIAO YAO, Singapore (SG); Qinggang Xing, Singapore (SG); Chien-Ming Lai, Tainan City (TW); Jun Zhu, Singapore (SG); Yu-Cheng Tung, Kaohsiung City (TW); ZHIBIAO ZHOU, Singapore (SG)

(21) Appl. No.: 15/253,908

(22) Filed: Sep. 1, 2016

(30) Foreign Application Priority Data
Jul. 26, 2016 (TW) 105123531

(51) Int. Cl. H01L 29/786; H01L 29/417

(52) U.S. Cl. CPC H01L 29/7869; H01L 29/41725

(57) ABSTRACT

An oxide semiconductor device includes an oxide semiconductor transistor and a protection wall. The protection wall extends in a vertical direction and surrounds the oxide semiconductor transistor. The oxide semiconductor transistor includes a first oxide semiconductor layer, and a bottom surface of the protection wall is lower than the first oxide semiconductor layer in the vertical direction. In the oxide semiconductor device of the present invention, the protection wall is used to surround the oxide semiconductor transistor for improving the ability of blocking environment substances from entering the oxide semiconductor transistor. The electrical stability and product reliability of the oxide semiconductor device are enhanced accordingly.

### BACKGROUND OF THE INVENTION

### 1. Field of the Invention

The present invention relates to an oxide semiconductor device, and more particularly, to an oxide semiconductor device including a protection wall surrounding an oxide semiconductor transistor for enhancing the protective ability.

### 2. Description of the Prior Art

Because of the properties of high mobility and low leakage current, oxide semiconductor materials such as indium gallium zinc oxide (IGZO) are widely applied in thin film transistors (TFTs) of display devices and field effect transistors (FETs) of integrated circuits. However, the semiconductor characteristics of the oxide semiconductor materials are directly dominated by the condition of oxygen vacancies in the oxide semiconductor materials, and the material properties of the oxide semiconductor layer tend to be influenced easily by environment substances, such as moisture, oxygen, and hydrogen. Accordingly, it is important to effectively block the environment substances from entering and influencing the oxide semiconductor material for improving the electrical stability and the product reliability of the oxide semiconductor device.

### SUMMARY OF THE INVENTION

An oxide semiconductor device is provided in the present invention, a protection wall surrounding an oxide semiconductor transistor is used to improve the blocking and protective abilities, and environment substances may be kept from entering and influencing an oxide semiconductor layer in the oxide semiconductor transistor. The electrical stability and the product reliability of the oxide semiconductor device may be enhanced accordingly.

According to an embodiment of the present invention, an oxide semiconductor device is provided. The oxide semiconductor device includes an oxide semiconductor transistor and a protection wall. The protection wall extends in a vertical direction and surrounds the oxide semiconductor transistor. The oxide semiconductor transistor includes a first oxide semiconductor layer, and a bottom surface of the protection wall is lower than the first oxide semiconductor layer in the vertical direction.

In the oxide semiconductor device of the present invention, the protection wall disposed surrounding the oxide semiconductor transistor may be used to enhance the ability of protecting the oxide semiconductor transistor laterally. The environment substances, such as moisture, oxygen, and hydrogen, may be kept from entering the oxide semiconductor layer for avoiding variations in the material properties and deterioration of the oxide semiconductor layer, and it is helpful in improving the electrical stability and the product reliability of the oxide semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating an oxide semiconductor device according to a first embodiment of the present invention.

FIG. 2 is a schematic drawing illustrating an oxide semiconductor device according to a second embodiment of the present invention.

FIG. 3 is a top view diagram of the oxide semiconductor device in the second embodiment.

FIG. 4 is a schematic drawing illustrating an oxide semiconductor device according to a third embodiment of the present invention.

FIG. 5 is a schematic drawing illustrating an oxide semiconductor device according to a fourth embodiment of the present invention.

FIG. 6 is a schematic drawing illustrating an oxide semiconductor device according to a fifth embodiment of the present invention.

FIG. 7 is a schematic drawing illustrating an oxide semiconductor device according to a sixth embodiment of the present invention.

### DETAILED DESCRIPTION

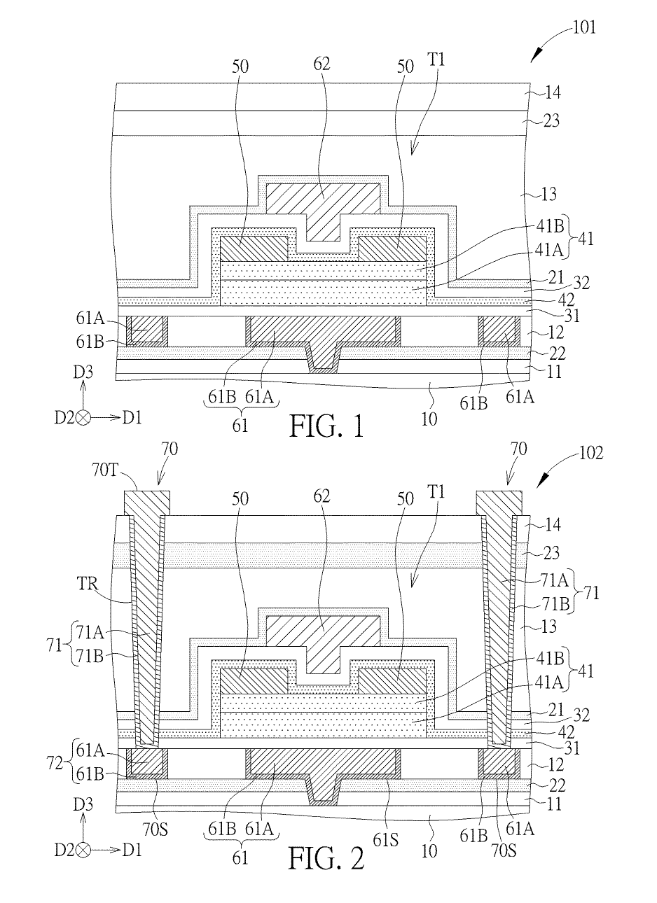

Please refer to FIG. 1. FIG. 1 is a schematic drawing illustrating an oxide semiconductor device according to a first embodiment of the present invention. As shown in FIG. 1, an oxide semiconductor device 101 is provided in this embodiment. The oxide semiconductor device 101 includes an oxide semiconductor transistor T1 disposed on a substrate 10. The substrate 10 may include a semiconductor substrate or a non-semiconductor substrate. The semiconductor substrate may include a silicon substrate, a silicon germanium substrate, or a silicon-on-insulator (SOI) substrate, and the non-semiconductor substrate may include a glass substrate, a plastic substrate, or a ceramic substrate, but not limited thereto. For example, when the substrate is a semiconductor substrate, a plurality of silicon-based field effect transistors (not shown) may be formed on the semiconductor substrate before the step of forming the oxide semiconductor transistor T1, but not limited thereto. In this embodiment, the oxide semiconductor transistor T1 may include a first gate electrode 61, a first gate insulation layer 31, a first oxide semiconductor layer 41, two source/drain electrodes 50, a second gate insulation layer 32, and a second gate electrode 62. The first gate electrode 61 is disposed under the first oxide semiconductor layer 41. At least a part of the first gate insulation layer 31 is disposed between the first gate electrode 61 and the first oxide semiconductor layer 41. The source/drain electrodes 50 are at least partially disposed on and contact the first oxide semiconductor layer 41. The second gate electrode 62 is disposed above the first oxide semiconductor layer 41. At least a part of the second gate insulation layer 32 is disposed between the second gate electrode 62 and the first oxide semiconductor layer 41, and a part of the second gate insulation layer 32 is disposed between the second gate electrode 62 and the source/drain electrodes 50. The oxide semiconductor transistor T1 in this embodiment may be regarded as a dual gate transistor structure, but the present invention is not limited to this. In some embodiments of the present invention, the oxide semiconductor transistor in the oxide semiconductor device may include other structures, such as a top gate structure, a bottom gate structure, triple gate structure, or other appropriate transistor structures according to other considerations.

As shown in FIG. 1, the oxide semiconductor device 101 may further include a first protection layer 21 and a second protection layer 22. The first protection layer 21 directly covers the oxide semiconductor transistor T1, and the second protection layer 22 is disposed under the oxide semiconductor transistor T1 in a vertical direction D3. The materials of the first protection layer 21 and the second protection layer 22 may include aluminum oxide (AlOₓ) or other suitable insulation materials capable of blocking environment substrates, such as moisture, oxygen, and hydrogen, but not limited thereto. A certain protection performance to the oxide semiconductor transistor T1 may be formed by disposing the first protection layer 21 and the second protection layer 22 on the upper side and the lower side in the vertical direction D3 respectively. In addition, as shown in FIG. 1, according to some considerations, the oxide semiconductor device 101 may further include a third protection layer 23 and a plurality of interlayer dielectrics, such as a dielectric layer 11, a dielectric layer 12, a dielectric layer 13, and a dielectric layer 14. The dielectric layer 11 is disposed between the second protection layer 22 and the substrate 10. The dielectric layer 12 is disposed between the first gate insulation layer 31 and the second protection layer 22. The dielectric layer 13 is disposed on the first protection layer 21 and covers the oxide semiconductor transistor T1. The dielectric layer 14 is disposed above the dielectric layer 13, and the third protection layer 23 is disposed between the dielectric layer 13 and the dielectric layer 14. In other words, all regions of the third protection layer 23 are higher than the oxide semiconductor transistor T1 in the vertical direction D3. The materials of the third protection layer 23 may be similar to or different from the materials of the first protection layer 21 and the second protection layer 22. The third protection layer 23 may be used to further enhance the ability of blocking the environment substances from entering the oxide semiconductor transistor T1. The dielectric layers 11, 12, 13, and 14 may include silicon oxynitride, silicon oxide, or other suitable dielectric materials. It is worth noting that the oxide semiconductor transistor T1 may further include a second oxide semiconductor layer disposed on the first oxide semiconductor layer 41 and the source/drain electrodes 50 according to some considerations. A part of the second oxide semiconductor layer 42 may be disposed between the second gate insulation layer 32 and each of the source/drain electrodes 50. On-current (Iₒₙ) of the oxide semiconductor transistor T1 may be effectively enhanced by the second oxide semiconductor layer 42 disposed along with the first gate electrode 61, the second gate electrode 62, and the first oxide semiconductor layer 41, and it is helpful in improving the electrical performance and expanding the application field of the oxide semiconductor transistor T1.

In this embodiment, the first gate electrode 61, the second gate electrode 62, and the source/drain electrodes 50 may include aluminum (Al), copper (Cu), titanium aluminide (TiAl), titanium (Ti), titanium nitride (TiN), tantalum (Ta), tantalum nitride (TaN), titanium aluminum oxide (TiAlO), or other appropriate conductive materials. For example, the first gate electrode 61 in this embodiment may be formed by filling a recess in the dielectric layer 12 with a first barrier layer 61B and a first conductive material 61A. Additionally, the recess mentioned above may further penetrate the second protection layer 22 and the dielectric layer 11, and the first gate electrode 61 formed in the recess may be connected downward to other units or circuits (not shown) in the substrate 10, but not limited thereto. The first barrier layer 61B may include titanium nitride, tantalum nitride, or other suitable barrier materials, and the first conductive material 61A may include materials with relatively lower resistivity, such as copper, aluminum, or tungsten, but not limited thereto. The first gate insulation layer 31 and the second gate insulation layer 32 may respectively include silicon oxide, silicon oxynitride, a high dielectric constant (high-k) material, or other appropriate dielectric materials. The high-k material mentioned above may include hafnium oxide (HfO₂), hafnium silicon oxide (HfSiO₄), hafnium silicon oxynitride (HfSiON), aluminum oxide (Al₂O₃), tantalum oxide (Ta₂O₅), zirconium oxide (ZrO₂), or other appropriate high-k materials. The first oxide semiconductor layer 41 and the second oxide semiconductor layer 42 may include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO2), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned materials, but not limited thereto. Additionally, the first oxide semiconductor layer 41 and the second oxide semiconductor layer 42 may be a single layer or a multiple layer structure formed by the above-mentioned oxide semiconductor materials, and the crystalline conditions of the first oxide semiconductor layer 41 and the second oxide semiconductor layer 42 are also not limited. For example, the first oxide semiconductor layer 41 and the second oxide semiconductor layer 42 may be amorphous IGZO (a-IGZO), crystal IGZO (c-IGZO), or C-axis aligned crystal IGZO (CAAC-IGZO). The first oxide semiconductor layer 41 may include a bottom layer 41A and a top layer 41B disposed on the bottom layer 41A, and the top layer may include an oxide semiconductor layer having relatively lower contact resistance between the source/drain electrodes 50 and the oxide semiconductor layer in comparison with the bottom layer 41A, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

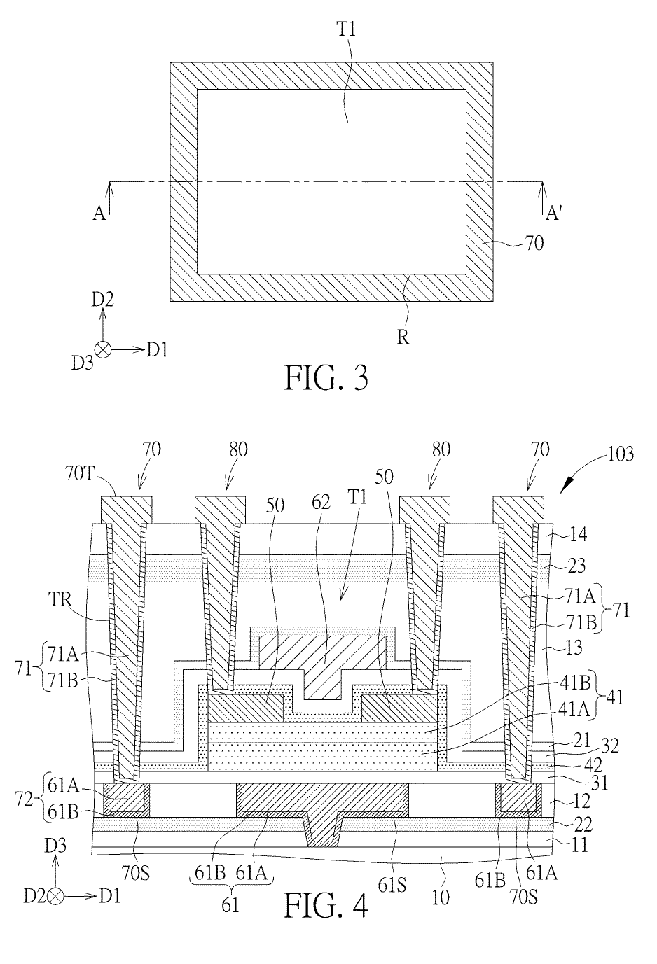

Please refer to FIG. 2 and FIG. 3. FIG. 2 is a schematic drawing illustrating an oxide semiconductor device 102 according to a second embodiment of the present invention, and FIG. 3 is a top view diagram of the oxide semiconductor device 102 in this embodiment. FIG. 2 may be regarded as a cross-sectional diagram taken along a line A-A′ in FIG. 3. As shown in FIG. 2 and FIG. 3, the differences between this embodiment and the first embodiment mentioned above is that the oxide semiconductor device 102 further includes a protection wall 70 extending in the vertical direction D3 and surrounding the oxide semiconductor transistor T1. From a top view of the oxide semiconductor device 102, such as FIG. 3, the protection wall 70 surrounds the oxide semiconductor transistor T1 in a horizontal direction (such as a first direction D1 and a second direction D2 shown in FIG. 3) orthogonal to the vertical direction D3 for enhancing the ability of blocking the environment substances from entering the oxide semiconductor transistor T1 laterally. The environment substances, such as moisture, oxygen, and hydrogen, may be kept from passing through regions (such as the dielectric layer 12, the first gate insulation layer 31, the second gate insulation layer 32, or the dielectric layer 13) on the lateral sides of the oxide semiconductor transistor T1 without the coverage of the first protection layer 21, the second protection layer 22, or the third protection layer 23 and entering the first oxide semiconductor layer 41 and/or the second oxide semiconductor layer 42 in the oxide semiconductor transistor T1. The deterioration of the first oxide semiconductor layer 41 and/or the second oxide semiconductor layer 42 may be avoided accordingly.

In this embodiment, a bottom surface 70S of the protection wall 70 is lower than the first oxide semiconductor layer 41 in the vertical direction D3, and a top surface 70T of the protection wall 70 is higher than the first protection layer 21 in the vertical direction D3 for forming the required blocking performance. Specifically, the protection wall 70 in this embodiment may include a first part 71 and a second part 72. The first part 71 is disposed on the second part 72, and the first part 71 is directly connected to the second part 72. The second part 72 is disposed in the dielectric layer 12, and the second part 72 may be formed by a part of the first conductive material 61A and a part of the first barrier layer 61B mentioned above. In other words, a part of the protection wall 70 and the first gate electrode 61 may be formed by the identical process together, and the bottom surface 70S of the protection wall 70 may be coplanar with a bottom surface 61S of the first gate electrode 61, but not limited thereto. Accordingly, the protection wall 70 in this embodiment may penetrate the dielectric layer 12 and directly contact the second protection layer 22. Additionally, the first part 71 of the protection wall 70 may be formed by filling a trench TR with a second barrier layer 71B and a second conductive material 71A. The second barrier layer 71B may include titanium nitride, tantalum nitride, or other suitable barrier materials, and the second conductive material 71A may include materials with relatively lower resistivity, such as copper, aluminum, or tungsten, but not limited thereto. For example, the first conductive material 61A and the second conductive material 71A may be copper preferably, and the first barrier layer 61B and the second barrier layer 71B may be tantalum nitride preferably for being compatible with the materials of the first conductive material 61A and the second conductive material 71A for generating a better blocking effect, but not limited thereto. Therefore, the protection wall 70 in this embodiment may include the second conductive material 71A and the second barrier layer 71B. The barrier layer 71B surrounds at least a part of the second conductive material 71A, and the protection wall 70 may be electrically floating preferably, but not limited thereto. In some embodiments of the present invention, the protection wall 70 may also be formed by insulation materials, such as aluminum oxide, or the protection wall 70 may also be electrically connected to other circuits according to other considerations. In other words, the protection wall 70 may include an insulation material or may be not electrically floating according to some considerations. For example, when the protection wall 70 is an insulation material, the protection wall 70, the first protection layer 21, the second protection layer 22, and the third protection layer 23 may be formed by one identical insulation material or be formed by different insulation materials.

As shown in FIG. 2 and FIG. 3, the trench TR may penetrate the dielectric layer 14, the third protection layer 23, the dielectric layer 13, the first protection layer 21, the second gate insulation layer 32, the second oxide semiconductor layer 42, and the first gate insulation layer 31 sequentially in the vertical direction D3. In other words, the trench TR also surrounds the oxide semiconductor transistor T1 in the horizontal direction orthogonal to the vertical direction D3, and the protection wall 70 also penetrates the dielectric layer 14, the third protection layer 23, the dielectric layer 13, the first protection layer 21, the second gate insulation layer 32, the second oxide semiconductor layer 42, and the first gate insulation layer 31. Therefore, the top surface 70T of the protection wall 70 may be higher than the third protection layer 23 in the vertical direction D3 preferably, and the bottom surface 70S of the protection wall 70 may be directly connected with the second protection wall. It is worth noting that, in some embodiments of the present invention, the second gate insulation layer 32, the second oxide semiconductor layer 42 and/or the first gate insulation layer 31 may not extend in the horizontal direction for being located between the first oxide semiconductor layer 42 and the protection wall 70 according to some considerations, and the protection wall 70 may not penetrate the second gate insulation layer 32, the second oxide semiconductor layer 42 and/or the first gate insulation layer 31. The protection wall 70 penetrates the first protection layer 21 and directly contacts the first protection layer 21, the second protection layer 22, and the third protection layer 23 for providing an all-round protection to the oxide semiconductor transistor T1 in the vertical direction D3 and the horizontal direction and blocking the environment substances from entering the oxide semiconductor transistor T1.

As shown in FIG. 3, from the top view diagram of the oxide semiconductor device 102, the protection wall 70 surrounds a semiconductor region R where the oxide semiconductor transistor T1 is disposed in the horizontal direction orthogonal to the vertical direction D3, and the shape of the protection wall 70 in the top view diagram of the oxide semiconductor device 102 may include a rectangle, a circle, or other suitable regular or irregular closed patterns. In some embodiments of the present invention, a plurality of the protection walls 70 may be disposed surrounding the oxide semiconductor transistor T1 for further enhancing the ability of blocking the environment substances. Additionally, in some embodiments of the present invention, a plurality of the oxide semiconductor transistors may be disposed in the transistor region R, and the protection wall 70 may surrounds the semiconductor transistors and provide protection for the semiconductor transistors.

Please refer to FIG. 4. FIG. 4 is a schematic drawing illustrating an oxide semiconductor device 103 according to a third embodiment of the present invention. As shown in FIG. 4, the difference between this embodiment and the second embodiment mentioned above is that the oxide semiconductor device 103 in this embodiment further include at least two source/drain contact structures 80 disposed on the source/drain electrodes 50 respectively, and the bottom surface 70S of the protection wall 70 is lower than the source/drain contact structures 80 in the vertical direction D3. The protection wall 70 in this embodiment may further surround the source/drain contact structures 80 in the horizontal direction. The source/drain contact structures 80 and the first part 71 of the protection wall 70 may be formed by the same material and/or by the seam process, but not limited thereto. For example, the main function of the protection wall 70 is blocking the environment substances from entering the oxide semiconductor transistor, and the material of the protection wall may be different from the material of the source/drain contact structure 80 when the protection wall is formed by conductive materials. In this embodiment, the protection wall 70 may be electrically floating or not, and the protection wall 70 is electrically isolated from the source/drain contact structures 80. Additionally, the source/drain contact structures 80 in this embodiment may also be selectively applied to the subsequent embodiments.

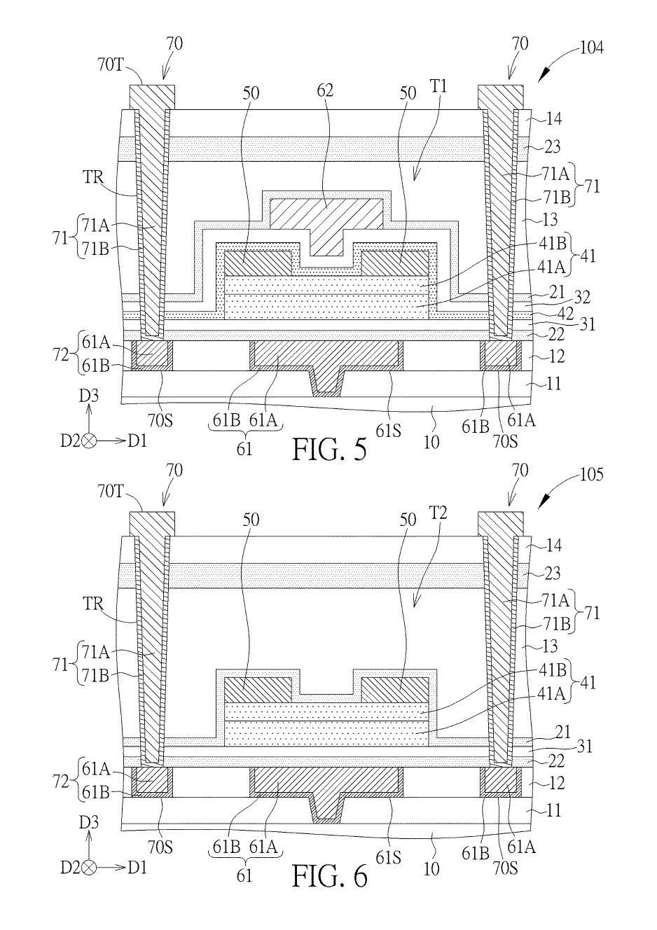

Please refer to FIG. 5. FIG. 5 is a schematic drawing illustrating an oxide semiconductor device 104 according to a fourth embodiment of the present invention. As shown in FIG. 5, the difference between this embodiment and the second embodiment mentioned above is that the second protection layer 22 in this embodiment is disposed on the dielectric layer 12, the first gate electrode 61, and the second part 72 of the protection wall 70. A part of the second protection layer 22 is disposed between the first gate electrode 61 and the first gate insulation layer 31. The first part 71 of the protection wall 70 is connected with the second part 72 bypassing through the second protection layer 22, and the protection wall further penetrates the second protection layer 22 accordingly. In other words, the protection wall 70 in this embodiment penetrates the third protection layer 23, the first protection layer 21, and the second protection layer 22 for further ensuring the protection and blocking effects formed by the protection wall 70, the third protection layer 23, the first protection layer 21, and the second protection layer 22 in the vertical direction D3 and the horizontal direction for the oxide semiconductor transistor T1.

Please refer to FIG. 6. FIG. 6 is a schematic drawing illustrating an oxide semiconductor device 105 according to a fifth embodiment of the present invention. As shown in FIG. 6, the difference between this embodiment and the fourth embodiment mentioned above is that an oxide semiconductor transistor T2 in the oxide semiconductor device 105 of this embodiment does not include the second gate electrode and the second gate insulation layer in the embodiments mentioned above, and the oxide semiconductor transistor T2 in this embodiment may be regarded as a bottom gate transistor structure. Additionally, the first protection layer 21 in this embodiment covers the first gate insulation layer 31, the first oxide semiconductor layer 41, and the source/drain electrodes 50, and the protection wall 70 penetrates the dielectric layer 14, the third protection layer 23, the dielectric layer 13, the first protection layer 21, the first gate insulation layer 31, and the second protection layer 22. It is worth noting that, in some embodiments of the present invention, the first gate insulation layer 31 may not extend in the horizontal direction for being located between the first oxide semiconductor layer 41 and the protection wall 70, and the protection wall 70 may not penetrate the first gate insulation layer 31 accordingly. The first protection layer 21 and the second protection layer 22 may be connected with each other at the periphery of the oxide semiconductor transistor for further enhancing the protection and blocking effect for the oxide semiconductor transistor.

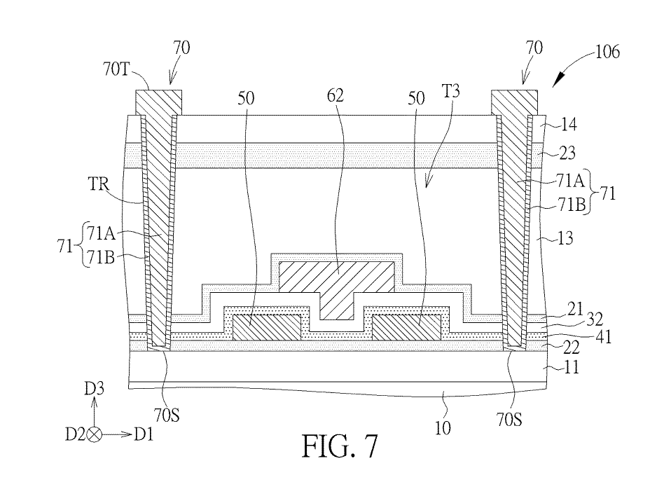

Please refer to FIG. 7. FIG. 7 is a schematic drawing illustrating an oxide semiconductor device 106 according to a sixth embodiment of the present invention. As shown in FIG. 7, the difference between this embodiment and the second embodiment mentioned above is that an oxide semiconductor transistor T3 in the oxide semiconductor device 106 of this embodiment does not include the first gate electrode and the first gate insulation layer in the embodiments mentioned above, and the oxide semiconductor transistor T3 in this embodiment may be regarded as a top gate transistor structure. Additionally, in this embodiment, the second protection layer 22 is disposed under the oxide semiconductor transistor T3, the source/drain electrodes 50 are disposed on the second protection layer 22 and disposed under the first oxide semiconductor layer 41, the first oxide semiconductor layer 41 is disposed on the source/drain electrodes 50 and the second protection layer 22, and a part of the first oxide semiconductor layer 41 is disposed between the second gate insulation layer 32 and each of the source/drain electrodes 50. The protection wall 70 in this embodiment may not include the second part in the embodiments mentioned above, and the protection wall 70 may only include the first part 71 penetrating the dielectric layer 14, the third protection layer 23, the dielectric layer 13, the first protection layer 21, the second gate insulation layer 32, the first oxide semiconductor layer 41, and the second protection layer 22. The protection wall 70 directly contacts the second protection layer 22. In some embodiments of the present invention, the second gate insulation layer 32 and/or the first oxide semiconductor layer 41 may not extend in the horizontal direction for being located between the protection wall 70 and the source/drain electrodes 50, and the protection wall may not penetrate the second gate insulation layer 32 and the first oxide semiconductor layer 41 accordingly, but not limited thereto.

To summarize the above descriptions, in the oxide semiconductor device of the present invention, the protection wall surrounding the oxide semiconductor transistor is used to improve the protective abilities for the oxide semiconductor transistor in the lateral directions. The environment substances, such as moisture, oxygen, and hydrogen, may be kept from entering the oxide semiconductor layer and deteriorating the material characteristics of the oxide semiconductor layer. The electrical stability and the product reliability of the oxide semiconductor device may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

1. An oxide semiconductor device, comprising:
an oxide semiconductor transistor, the oxide semiconductor transistor comprising a first oxide semiconductor layer; and
a protection wall extending in a vertical direction and surrounding the oxide semiconductor transistor, wherein a bottom surface of the protection wall is lower than the first oxide semiconductor layer in the vertical direction.

2. The oxide semiconductor device of claim 1, wherein from a top view of the oxide semiconductor device, the protection wall surrounds the oxide semiconductor transistor in a horizontal direction orthogonal to the vertical direction.

3. The oxide semiconductor device of claim 1, further comprising:
a first protection layer covering the oxide semiconductor transistor, wherein a top surface of the protection wall is higher than the first protection layer in the vertical direction.

4. The oxide semiconductor device of claim 3, wherein the protection wall penetrates the first protection layer.

5. The oxide semiconductor device of claim 3, wherein the oxide semiconductor transistor further comprising:
two source/drain electrodes, wherein the source/drain electrodes contact the first oxide semiconductor layer.

6. The oxide semiconductor device of claim 5, further comprising:
two source/drain contact structures disposed on the source/drain electrodes respectively, wherein the bottom surface of the protection wall is lower than the source/drain contact structures in the vertical direction.

7. The oxide semiconductor device of claim 5, wherein the oxide semiconductor transistor further comprising:
a first gate electrode disposed under the first oxide semiconductor layer; and
a first gate insulation layer, wherein at least a part of the first gate insulation layer is disposed between the first gate electrode and the first oxide semiconductor layer, and the source/drain electrodes are at least partially disposed on the first oxide semiconductor layer.

8. The oxide semiconductor device of claim 7, wherein the protection wall penetrates the first gate insulation layer.

9. The oxide semiconductor device of claim 7, further comprising:
a second protection layer disposed under the first gate electrode, wherein the protection wall directly contacts the second protection layer.

10. The oxide semiconductor device of claim 7, further comprising:
a second protection layer disposed between the first gate electrode and the first gate insulation layer, wherein the protection wall penetrates the second protection layer.

11. The oxide semiconductor device of claim 1, wherein the oxide semiconductor transistor further comprises:
a second gate electrode disposed above the first oxide semiconductor layer; and
a second gate insulation layer, wherein at least a part of the second gate insulation layer is disposed between the second gate electrode and the first oxide semiconductor layer.

12. The oxide semiconductor device of claim 11, wherein the protection wall penetrates the second gate insulation layer.

13. The oxide semiconductor device of claim 11, wherein the protection wall penetrates the first oxide semiconductor layer.

14. The oxide semiconductor device of claim 11, wherein the oxide semiconductor transistor further comprises:
two source/drain electrodes, wherein the source/drain electrodes are at least partially disposed on the first oxide semiconductor layer; and
a second oxide semiconductor layer disposed on the first oxide semiconductor layer and the source/drain electrodes, wherein a part of the second oxide semiconductor layer is disposed between the second gate insulation layer and each of the source/drain electrodes.

15. The oxide semiconductor device of claim 14, wherein the protection wall penetrates the second oxide semiconductor layer.

16. The oxide semiconductor device of claim 11, wherein the oxide semiconductor transistor further comprises:
two source/drain electrodes disposed under the first oxide semiconductor layer, wherein a part of the first oxide semiconductor layer is disposed between the second gate insulation layer and each of the source/drain electrodes.

17. The oxide semiconductor device of claim 16, further comprising:
a second protection layer disposed under the oxide semiconductor transistor, wherein the source/drain electrodes are disposed on the second protection layer, and the protection wall directly contacts the second protection layer.

18. The oxide semiconductor device of claim 17, wherein the protection wall penetrates the second protection layer.

19. The oxide semiconductor device of claim 1, wherein the protection wall comprises an insulation material.

20. The oxide semiconductor device of claim 1, wherein the protection wall comprises:
a conductive material; and
a barrier layer surrounding at least a part of the conductive material, wherein the protection wall is electrically floating.
